(19) United States
(12) Patent Application Publication
(10) Pub. No.: US 2016/0238649 A1
(43) Pub. Date: Aug. 18, 2016

(54) SMALL FORM-FACTOR PLUGGABLE MODULE WITH GROUND FAULT DETECTION CIRCUITRY

(71) Applicant: Carrier Corporation, Farmington, CT (US)

(72) Inventor: William Edwards, Lakewood Ranch, FL (US)

(21) Appl. No.: 15/044,254

(22) Filed: Feb. 16, 2016

Related U.S. Application Data
(60) Provisional application No. 62/117,318, filed on Feb. 17, 2015.

(51) Int. Cl. G01R 31/02; G08B 21/18

(52) U.S. Cl. CPC G01R 31/025; G08B 21/18

(57) ABSTRACT

A fire control panel including an Ethernet network interface card comprising a card ground fault detection circuit, and a small form-factor pluggable module in communication with the Ethernet network interface card, the small form-factor pluggable module comprising a module ground fault detection circuit configured to detect a ground connection in field wiring. A method of detecting a ground fault within a fire control panel, the fire control panel including an Ethernet network interface card, including a processor and a network ground fault detection circuit in communication with the processor, and a small form-factor pluggable module in communication with the Ethernet network interface card, the small form-factor pluggable module including a module ground fault detection circuit, the method including the steps: operating the card ground fault detection circuit to enter a detection mode, and operating the module ground fault detection circuit to enter a detection mode.

### CROSS REFERENCE TO RELATED APPLICATIONS

The present application is related to, and claims the priority benefit of, U.S. Provisional Patent Application Ser. No. 62/117,318 filed Feb. 17, 2015, the contents of which are hereby incorporated in their entirety into the present disclosure.

### TECHNICAL FIELD OF THE DISCLOSED EMBODIMENTS

The presently disclosed embodiments generally relate to network communication modules, and more particularly, to a small form factor pluggable module with ground fault detection circuitry.

### BACKGROUND OF THE DISCLOSED EMBODIMENTS

Generally, commercial fire alarm systems include fire alarm control panels networked together or networked with other fire alarm equipment including terminals or workstations. The network utilized by the fire alarm control panel may be an Ethernet network as governed by the IEEE 802.3 standard. The 802.3 standard governs the physical layer (layer 1) and media access control (MAC) of the data link layer (layer 2) in Ethernet. Devices such as data switches, hubs, and routers, provide the nodes and infrastructure of the Ethernet. The 802.3 standard requires isolation between ground and the Ethernet cabling for safety and also isolation from port to port. Intentional direct current paths to ground from the Ethernet cabling are not permitted under the 802.3 standard.

The Standard for Control Units and Accessories for Fire Alarm Systems (UL 864, 9th Edition) presently governs all fire alarm control panels and connected equipment. To comply with UL 864, devices used with a fire alarm control panel for control applications should be capable of reporting earth ground connections that have the potential to affect system performance. There is therefore need in the art for a fire alarm control panel utilizing an Ethernet connection that may detect such earth ground connections.

### SUMMARY OF THE DISCLOSED EMBODIMENTS

In one aspect, a fire alarm control panel is provided. The fire alarm control panel includes an Ethernet network interface card and a small form-factor pluggable (SFP) module in communication with the Ethernet network interface card.

The network interface card includes a card ground fault detection circuit. The card ground fault detection circuit includes a first resistive component and a second resistive component. One side of the first resistive component is in electrical communication with a system power source, and the other side of the first resistive component is in electrical communication with one side of the second resistive component to form a card reference point. The other side of the second resistive component is in electrical communication with a card circuit common connection. In one embodiment, the first resistive component and the second resistive component include a resistive value greater than or equal to approximately 100 kilo ohms. The card ground fault detection circuit further includes a card switching device. One side of the card switching device is in electrical communication with the card reference point, and the other side of card switching device is in electrical communication with a chassis ground connection. The card ground fault detection circuit further includes a comparator circuit and a card microcontroller unit. The input of the comparator circuit is in electrical communication with the card reference point, and the output of the comparator circuit is in electrical communication with the card microcontroller unit.

The SFP module includes a module ground fault detection circuit. In one embodiment, the module ground fault detection circuit includes at least one switching device. One side of the at least one switching device is in electrical communication with a center tap of at least one Ethernet transformer, and the other side of the at least one switching device is in electrical communication with one side of a module resistive component. In one embodiment, the at least one Ethernet transformer is selected from the group consisting of a transmitter transformer and a receiver transformer. The other side of the module resistive component is in electrical communication with a module circuit common connection.

In the same embodiment, the module ground fault detection circuit further includes a module microcontroller unit in operable communication with the at least one switching device. The module microcontroller is in further communication with the card microcontroller unit via a data connection.

In another embodiment, the module ground fault detection circuit includes at least one Ethernet transformer, a first module resistive component, including a first module resistive component value, in communication with a second module resistive component, including a second module resistive component value, to form a module reference point, the first module resistive component in further communication with an isolated voltage to form an isolated voltage reference point, and the second module resistive component in further communication with an earth ground connection, a module switching device in communication with the module reference point, the module switching device in further communication with a ground connection, a module operational amplifier circuit in communication with the module reference point a module microcontroller unit in communication with the operational amplifier circuit and the card microcontroller unit, an isolator circuit in communication with the module microcontroller unit, a converter circuit in communication with the isolated voltage reference point in further communication with the module microcontroller unit, a third module resistive component, including a third module resistive component value, in communication with a center tap of the at least one Ethernet transformer and the isolated voltage reference point, and a fourth module resistive component, including a fourth module resistive component value, in communication with a center tap of the at least one Ethernet transformer and an earth ground connection. In one embodiment, the first resistive component, the second resistive component, the third resistive component, and the fourth resistive component include a resistive value greater than or equal to approximately 100 kilo

In one aspect, a method of detecting a ground fault within a network of devices including an Ethernet interface card including a card ground fault detection circuit and a SFP module in communication with the Ethernet interface card, the SFP module including a card ground detection circuit is provided. The method includes the step of operating the card ground fault detection circuit to enter a detection mode. In one embodiment, operating the card ground fault detection circuit to enter a detection mode includes operating a card switching device to be placed in a closed position.

The method further includes the step of operating the module ground fault detection circuit to enter a detection mode. In one embodiment, operating the module ground fault detection circuit to enter a detection mode includes operating at least one module switching device to be placed in a closed position.

In one embodiment, the method includes the step of operating the module ground fault detection circuit to communicate a ground fault to the Ethernet network interface card if a ground fault is detected.

### BRIEF DESCRIPTION OF THE DRAWINGS

The embodiments and other features, advantages and disclosures contained herein, and the manner of attaining them, will become apparent and the present disclosure will be better understood by reference to the following description of various exemplary embodiments of the present disclosure taken in conjunction with the accompanying drawings, wherein:

FIG. 1 illustrates a schematic diagram of a network including a small form-factor pluggable module ground detection circuit according to one embodiment of the present disclosure;

FIG. 2 illustrates a schematic diagram of a network including a small form-factor pluggable module ground detection circuit according to another embodiment of the present disclosure;

FIG. 3 illustrates a schematic flow diagram of a method for detecting a ground fault within a network according to one embodiment of the present disclosure.

### DETAILED DESCRIPTION OF THE DISCLOSED EMBODIMENTS

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

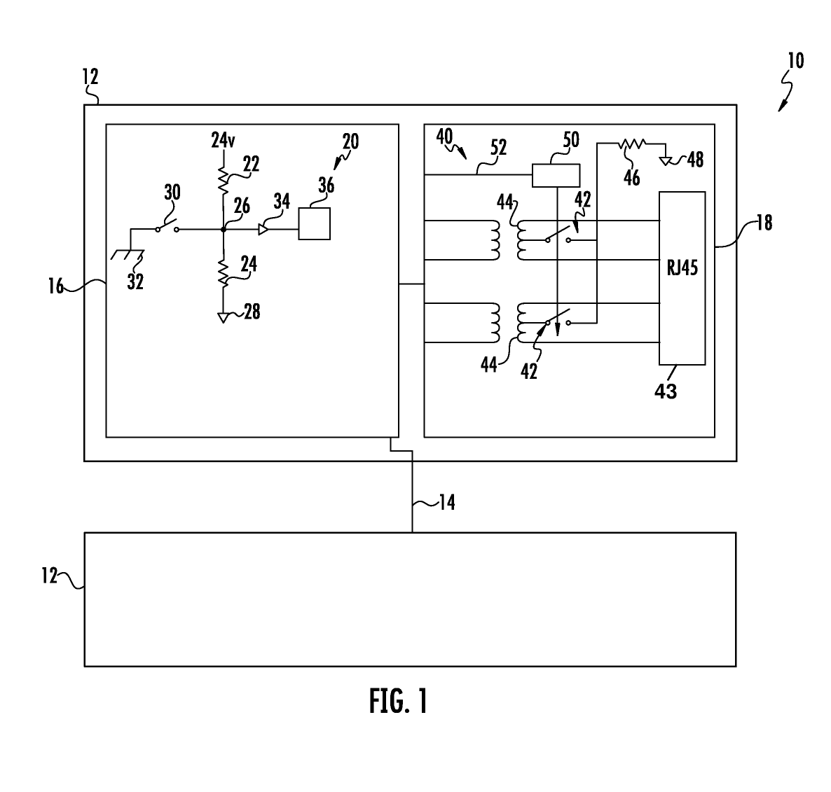

FIG. 1 illustrates an embodiment of a network, generally indicated at 10. The network includes a first fire alarm control panel 12 in communication with a second fire alarm control panel 12 via an Ethernet connection 14. It will be appreciated that the first fire alarm control panel 12 may also be in communication with a workstation (not shown), for example a computer configured to monitor the fire alarm system of a building, to name one non-limiting example.

The fire alarm control panel 12 is configured to monitor one or more detectors. The detectors may include fire detectors, smoke detectors, radiation detectors, heat detectors, carbon monoxide detectors, ozone detectors and/or other gas detectors, to name a few non-limiting examples, and may provide an indication of an alarm condition. The fire alarm control panel 12 is also configured to monitor manual alarm triggers, such as a pull device, push button triggers, and glass break triggers to name a few non-limiting examples. The fire alarm control panel 12 may include a user interface, memory, and microprocessor (not shown). The fire alarm control panel 12 may be implemented as software on a personal computer or as a standalone piece of hardware.

The fire alarm control panel 12 includes an Ethernet network interface card 16 and a small form-factor pluggable (SFP) module 18 in communication with the Ethernet network interface card 16. For example the SFP module 18 may be inserted into a port on the Ethernet network interface card 16 to provide the Ethernet connection 14 within the network 10

The network interface card 16 includes a card ground fault detection circuit 20. The card ground fault detection circuit 20 includes a first resistive component 22 and a second resistive component 24. One side of the first resistive component 22 is in electrical communication with a system power source, for example 24 VDC to name one non-limiting example. The other side of the first resistive component 22 is in electrical communication with one side of the second resistive component 24 to form a card reference point 26. The other side of the second resistive component 24 is in electrical communication with a card circuit common connection 28. In one embodiment, the first resistive component 22 and the second resistive component 24 include a resistive value greater than or equal to approximately 100 kilo ohms. It will be appreciated that the first resistive component 22 and the second resistive component 24 may have a resistive value less than approximately 100 kilo ohms. The card ground fault detection circuit 20 further includes a card switching device 30. One side of the card switching device 30 is in electrical communication with the card reference point 26, and the other side of card switching device 30 is in electrical communication with a chassis ground connection 32. The card ground fault detection circuit 20 further includes an operational amplifier circuit 34 and a card microcontroller unit 36. The input of the comparator circuit 34 is in electrical communication with the card reference point 26, and the output of the comparator circuit 34 is in electrical communication with the card microcontroller unit 36. It will be appreciated that the card microcontroller unit 36 may include an integrated analog-to-digital converter.

During operation of the card ground fault detection circuit 20, the first card resistive component 22 and the second card resistive component 24 create a voltage reference from the system power at card reference point 26. The reference voltage at reference point 26 is monitored by the microcontroller unit 36. When the card switching device 30 is placed in a closed position, any resistance from any field wiring to the network interface card 16 will appear in parallel with either the first card resistive component 22 or the second card resistive component 24; thus, causing a detectable shift in the reference voltage. A shift of adequate size will indicate the presence of a ground fault.

In the embodiment shown in FIG. 1, the SFP module 18 includes a module ground fault detection circuit 40. The module ground fault detection circuit 40 includes at least one switching device 42. It will be appreciated that the at least one switching device 48 may include a relay to name one non-limiting example. One side of the at least one switching device 42 is in electrical communication with a center tap of at least one Ethernet transformer 44, and the other side of the at least one switching device 42 is in electrical communication with one side of a module resistive component 46. In one embodiment, the at least one Ethernet transformer 44 is selected from the group consisting of a transmitter transformer and a receiver transformer. The transmitter transformer is configured to transmit signals to the Ethernet network interface card 16. The receiver transformer is configured to receive signals from the Ethernet network interface card 16. The other side of the module resistive component 46 is in electrical communication with a module circuit common connection 48.

In the embodiment shown, the module ground fault detection circuit 40 further includes a module microcontroller unit 50 in operable communication with the at least one switching device 42. The module microcontroller unit 50 is configured to operate the at least one switching device 42 between an open position and closed position. For example, the module microcontroller unit 50 is configured to open and close the at least one switching device 42 to close the connection from the center tap of the at least one Ethernet transformer 44 to the module circuit common connection 48. The module microcontroller 50 is in further communication with the card microcontroller unit 36 via a data connection 52. The card microcontroller unit 36 and the module microcontroller unit 50 are configured to send and receive control signals via the data connection 52.

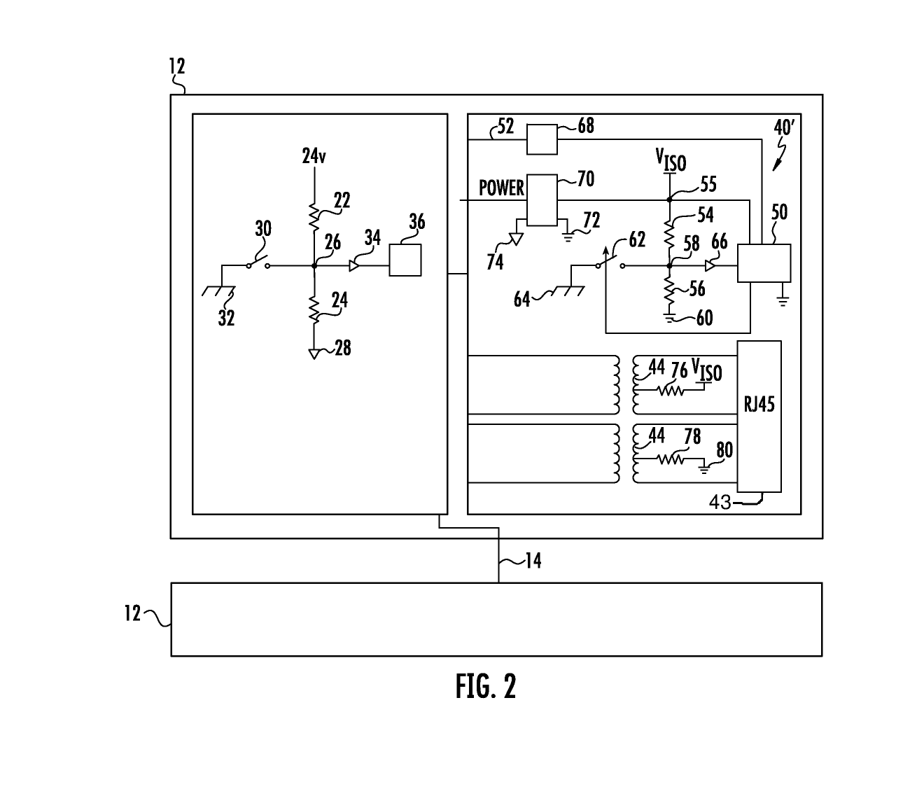

In another embodiment, as shown in FIG. 2, the module ground fault detection circuit 40′ includes a first module resistive component 54 and a second module resistive component 56. One side of the first module resistive component 54 is in electrical communication with an isolated voltage, designated as V_{ISO}, for example 24 VDC to name one non-limiting example, to form an isolation reference point 55. The other side of the first module resistive component 54 is in electrical communication with one side of the second module resistive component 56 to form a module reference point 58. The other side of the second module resistive component 56 is in electrical communication with an earth ground 60. It will be appreciated that the first module resistive component 54 and the second module resistive component 56 may have a resistive value greater than or equal to approximately 100 kilo ohms.

The module ground fault detection circuit 40′ further includes a module switching device 62. One side of the module switching device 62 is in electrical communication with the module reference point 58, and the other side of module switching device 62 is in electrical communication with a chassis ground connection 64. The module ground fault detection circuit 40′ further includes a module operational amplifier circuit 66 and the module microcontroller unit 50. The module microcontroller unit 50 is configured to operate the module switching device 62 between an open position and closed position. The input of the module operational amplifier circuit 66 is in electrical communication with the module reference point 58, and the output of the module comparator circuit 66 is in electrical communication with the module microcontroller unit 50. The module microcontroller 50 is also in communication with an output of an isolator circuit 68. The input of the isolator circuit is in communication with the card microcontroller unit 36 via a data connection 52. The module microcontroller 50 is in further electrical communication with the isolation reference point 55. The isolation reference point 55 is in electrical communication with an output of a converter circuit 70, for example a DC/DC converter to name one non-limiting example. Another output of the converter circuit is in electrical communication with earth ground 72. One input of the converter circuit 70 is in communication with the system power, and another input is in electrical communication with a circuit common connection 74. The card microcontroller unit 36 and the module microcontroller unit 50 are configured to send and receive control signals via the data connection 52.

One side of a third module resistive component 76 is in electrical communication with a center tap of at least one Ethernet transformer 44, and the other side of a third module resistive component 76 is in electrical communication with the isolation reference point 55. One side of a fourth module resistive component 78 is in electrical communication with a center tap of at least one Ethernet transformer 44, and the other side of a fourth module resistive component 78 is in electrical communication with an earth ground 80.

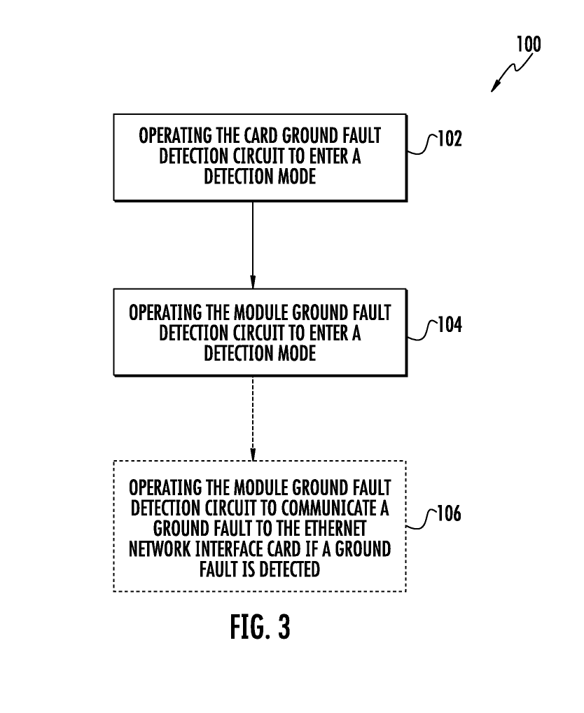

FIG. 3 illustrates a method of detecting a ground fault within the network 10, generally indicated at 100. The method 100 includes the step 102 of operating the card ground fault detection circuit 20 to enter a detection mode. In one embodiment, operating the card ground fault detection circuit 20 to enter a detection mode includes operating the card switching device 30 to be placed in a closed position. For example the microprocessor (not shown) of the fire alarm control panel 12 sends a signal commanding the card switching device 30 to be placed in a closed position. It will be appreciated that the processor may send the signal commanding the card switching device 30 to be placed in a closed position at pre-determined intervals or randomly.

The method further includes the step 104 of operating the module ground fault detection circuit 40 or 40′ to enter a detection mode. It will be appreciated that the module ground fault detection circuit 40 or 40′, within each SFP module 18 of the system 10, may enter a detection mode simultaneously or each ground fault detection circuit 40 or 40′ within each SFP module 18 may be selectively isolated for individual testing. In one embodiment, operating the module ground fault detection circuit 40 or 40′ to enter a detection mode includes operating the at least one module switching device 42 or 62 to be placed in a closed position. It will be appreciated that the module ground fault detection circuit 40 or 40′ may enter a detection mode at pre-determined intervals or randomly. For example, in the embodiment shown in FIG. 1, the processor sends a signal to the module microcontroller unit 50 to place either or both of the at least one module switching devices 42 in a closed position. In the embodiment shown in FIG. 2, the module microcontroller unit 50 commands the module switching device 62 to be placed in a closed position. Once the at least one switching device 42 or 62 is placed in a closed position, any resistance to earth ground will appear in parallel with the first card resistive component 22 and the second card resistive component 24; thus, indicating that a ground fault has occurred.

In one embodiment, the method includes the step 106 of operating the module ground fault detection circuit 40 or 40′ to communicate a ground fault to the Ethernet network interface card 16 if a ground fault is detected. For example, if it is determine that a field wiring connection indicates a ground fault, the module microcontroller unit 50 communicates a signal to the card microcontroller unit 36 via the data connection 52. Once a ground fault is communicated, a signal (either an audio or visual signal to name a couple of non-limiting examples) may be communicated to alert the appropriate personnel that a fault has occurred.

It will therefore be appreciated that the present embodiments include a ground fault detection circuit 40 or 40′ within a SFP module 18 to reduce the overall cost and conserve space within a fire alarm control panel 12, and simplifies the communication of ground fault detections that may occur within the system 10.

While the invention has been illustrated and described in detail in the drawings and foregoing description, the same is to be considered as illustrative and not restrictive in character, it being understood that only certain embodiments have been shown and described and that all changes and modifications that come within the spirit of the invention are desired to be protected.

What is claimed is:

1. A fire control panel comprising:
an Ethernet network interface card comprising a card ground fault detection circuit; and
a small form-factor pluggable module in communication with the Ethernet network interface card, the small form-factor pluggable module comprising a module ground fault detection circuit configured to detect a ground detection in field wiring.

2. The fire control panel of claim 1, wherein the card ground fault detection circuit comprises:
a first card resistive component, including a first card resistive component values, in communication with a second card resistive component, including a second card resistive component value, to form a card reference point, the first card resistive component in further communication with a power source and the second card resistive component in further communication with a circuit common connection;
a card switching device in communication with the card reference point, the card switching device in further communication with a ground connection;
a card operational amplifier circuit in communication with the card reference point; and
a card microcontroller unit in communication with the operational amplifier circuit.

3. The fire control panel of claim 2, wherein the first card resistive component value and the second card resistive component value are greater than or equal to approximately 100 kilo ohms.

4. The fire control panel of claim 2, wherein the module ground fault detection circuit comprises:
at least one Ethernet transformer;
at least one module switching device in communication with each of the at least one Ethernet transformers;
a module resistive component in communication with each of the at least one module switching devices and in further communication with a circuit common; and
a module microcontroller unit in communication with each the at least one switching devices, and in further communication with the card microcontroller unit.

5. The fire control panel of claim 3, wherein the at least one Ethernet transformer is selected from the group consisting of a transmitter transformer and a receiver transformer.

6. The fire control panel of claim 3, wherein the at least one switching device is in communication with a center tap of each of the at least one Ethernet transformers.

7. The fire control panel of claim 3, wherein the module microcontroller unit is configured to operate the at least one switch.

8. The fire control panel of claim 3, wherein the module ground fault detection circuit comprises:
at least one Ethernet transformer;
a first module resistive component, including a first module resistive component value, in communication with a second module resistive component, including a second module resistive component value, to form a module reference point, the first module resistive component in further communication with an isolated voltage to form an isolated voltage reference point, and the second module resistive component in further communication with an earth ground connection;
a module switching device in communication with the module reference point, the module switching device in further communication with a ground connection;
a module operational amplifier circuit in communication with the module reference point;
a module microcontroller unit in communication with the operational amplifier circuit and the card microcontroller unit;
an isolator circuit in communication with the module microcontroller unit;
a converter circuit in communication with the isolated voltage reference point in further communication with the module microcontroller unit;
a third module resistive component, including a third module resistive component value, in communication with a center tap of the at least one Ethernet transformer and the isolated voltage reference point; and
a fourth module resistive component, including a fourth module resistive component value, in communication with a center tap of the at least one Ethernet transformer and an earth ground connection

9. The fire control panel of claim 8, wherein the first module resistive component value, the second module resistive component value, the third module resistive component value, and the fourth module resistive component value are greater than or equal to approximately 100 kilo ohms.

10. A small form-factor pluggable module comprising:
a ground fault detection circuit, the ground fault detection circuit comprising:
at least one Ethernet transformer;
at least one switching device in communication with each of the at least one Ethernet transformers;
a resistive component in communication with each of the at least one switching devices and a circuit common; and
a module microcontroller unit in communication with each the at least one switching devices.

11. The module of claim 10, wherein the at least one Ethernet transformer is selected from the group consisting of a transmitter transformer and a receiver transformer.

12. The module of claim 10 wherein the at least one switching device is in communication with a center tap of each of the at least one Ethernet transformers.

13. The module of claim 12, wherein the microcontroller unit is configured to operate the at least one switching device.

14. A small form-factor pluggable module comprising:
a ground fault detection circuit, the ground fault detection circuit comprising:
at least one Ethernet transformer;
a first module resistive component, including a first module resistive component value, in communication with a second module resistive component, including a second module resistive component value, to form a module reference point, the first module resistive component in further communication with an isolated voltage to form an isolated voltage reference point, and the second module resistive component in further communication with an earth ground connection;
a module switching device in communication with the module reference point, the module switching device in further communication with a ground connection;
a module operational amplifier circuit in communication with the module reference point;
a module microcontroller unit in communication with the operational amplifier circuit and the card microcontroller unit;
an isolator circuit in communication with the module microcontroller unit;
a converter circuit in communication with the isolated voltage reference point in further communication with the module microcontroller unit;
a third module resistive component, including a third module resistive component value, in communication with a center tap of the at least one Ethernet transformer and the isolated voltage reference point; and
a fourth module resistive component, including a fourth module resistive component value, in communication with a center tap of the at least one Ethernet transformer and an earth ground connection

15. The module of claim 14, wherein the first module resistive component value, the second module resistive component value, the third module resistive component value, and the fourth module resistive component value are greater than or equal to approximately 100 kilo ohms.

16. A method of detecting a ground fault within a fire control panel, the fire control panel including an Ethernet network interface card, including a processor and a network ground fault detection circuit in communication with the processor, and a small form-factor pluggable module in communication with the Ethernet network interface card, the small form-factor pluggable module including a module ground fault detection circuit, the method comprising the steps:
(a) operating the card ground fault detection circuit to enter a detection mode; and
(b) operating the module ground fault detection circuit to enter a detection mode.

17. The method of claim 16 further comprising the step:
(c) operating the module ground fault detection circuit to communicate a ground fault to the Ethernet network interface card if a ground fault is detected.

18. The method of claim 16, wherein the card ground detection circuit comprises:
a first card resistive component, including a first card resistive component values, in communication with a second card resistive component, including a second card resistive component value, to form a card reference point, the first card resistive component in further communication with a power source and the second card resistive component in further communication with a circuit common connection;
a card switching device in communication with the card reference point, the card switching device in further communication with a ground connection;
a card comparator circuit in communication with the card reference point; and
a card microcontroller unit in communication with the card comparator circuit.

19. The method of claim 17, wherein the module ground detection circuit comprises:
at least one Ethernet transformer;
at least one module switching device in communication with each of the at least one Ethernet transformers;
a module resistive component in communication with each of the at least one module switching devices and in further communication with a circuit common; and
a module microcontroller unit in communication with each the at least one switching devices, and in further communication with the card microcontroller unit.

20. The method of claim 17, wherein the module ground fault detection circuit comprises:
at least one Ethernet transformer;
a first module resistive component, including a first module resistive component value, in communication with a second module resistive component, including a second module resistive component value, to form a module reference point, the first module resistive component in further communication with an isolated voltage to form an isolated voltage reference point, and the second module resistive component in further communication with an earth ground connection;
a module switching device in communication with the module reference point, the module switching device in further communication with a ground connection;
a module operational amplifier circuit in communication with the module reference point;
a module microcontroller unit in communication with the operational amplifier circuit and the card microcontroller unit;
an isolator circuit in communication with the module microcontroller unit;
a converter circuit in communication with the isolated voltage reference point in further communication with the module microcontroller unit;
a third module resistive component, including a third module resistive component value, in communication with a center tap of the at least one Ethernet transformer and the isolated voltage reference point; and
a fourth module resistive component, including a fourth module resistive component value, in communication with a center tap of the at least one Ethernet transformer and an earth ground connection

21. The method of claim 19 or claim 20, wherein step (a) comprises operating the card switching device to be placed in a closed position.

22. The method of claim 19 or claim 20, wherein step (b) comprises operating the at least one switching device to be placed in a closed position.
